(19) United States
(12) Patent Application Publication
(10) Pub. No.: US 2010/0264429 A1
(43) Pub. Date: Oct. 21, 2010

(54) LIGHT EMITTING DEVICE AND ELECTRONIC DEVICE USING THE SAME

(75) Inventor: Yu-Huan Liu, TAIPEI COUNTY (TW)

Correspondence Address: QUINTERO LAW OFFICE, PC, 615 Hampton Dr, Suite A202, Venice, CA, 90291, US

(73) Assignee: EVER LIGHT ELECTRONICS CO., LTD., TAIPEI (TW)

(21) Appl. No.: 12/606,020

(22) Filed: Oct. 26, 2009

(30) Foreign Application Priority Data
Apr. 20, 2009 (TW) TW98112990

(51) Int. Cl. H01L 33/00

(52) U.S. Cl. 257/88; 257/98; 257/E33.068; 257/E33.059

(57) ABSTRACT

A light emitting device and an electronic device using the same are provided. The light emitting device includes a light emitting chip having a wavelength between 460 nm and 650 nm and phosphor powders, in which the phosphor powders can be stimulated by light emitted from the chip to emit light with a wavelength between 700 nm and 1200 nm. The phosphor powders are selected from the group consisting of Cu-doped CdS, Cu-doped SeS, Cu-doped CdTe and combinations thereof.

### CROSS REFERENCE TO RELATED APPLICATIONS

This Application claims priority of Taiwan Patent Application No. 098112990, filed on Apr. 20, 2009, the entirety of which is incorporated by reference herein.

### BACKGROUND OF THE INVENTION

1. Field of the Invention

The present invention relates to a light emitting device, and in particular, to a high intensity infrared light emitting device.

2. Description of the Related Art

Light emitting diodes (LEDs) have been widely applied in various fields. For example, visible LEDs comprising blue light, red light and green light LEDs can be applied in the illumination and display fields. And infrared LEDs, illuminating light in an invisible light region can be applied in the wireless remote control and sensing fields.

Generally, the method for fabricating the conventional infrared LEDs comprises using GaAs as a substrate, and depositing a light emitting layer with materials similar to the substrate, for example, GaAs or GaAlAs materials, on the substrate. The conventional infrared LEDs directly emit infrared light with a wavelength between 850 nm and 940 nm. The conventional infrared LEDs, however, have weak intensities and narrow light emitting wavelength ranges.

Therefore, a light emitting device emitting infrared light with high intensity is needed.

### BRIEF SUMMARY OF INVENTION

A light emitting device is provided. An exemplary embodiment of a light emitting device comprises: a light emitting chip having a wavelength between 460 nm and 650 nm; an encapsulant material encapsulating the light emitting chip; a phosphor powder dispersed in the encapsulant material, stimulated by light emitted from the light emitting chip to emit light with a wavelength between 700 nm and 1200 nm, wherein the phosphor powder is selected from the group consisting of Cu-doped CdS, Cu-doped SeS, Cu-doped CdTe and combinations thereof.

An exemplary embodiment of an electronic device having the light emitting device is provided. The electronic device comprises an optical sensing input device, a remote controller or a local network signal transceiver.

Another exemplary embodiment of a light emitting device comprises: a light emitting chip having a wavelength between 460 nm and 650 nm; an encapsulant material encapsulating the light emitting chip; a phosphor powder dispersed in the encapsulant material, stimulated by light emitted from the light emitting chip to emit light with a wavelength between 700 nm and 1200 nm, wherein the phosphor powder is selected from the group consisting of Na-doped BaSO₄, K-doped BaSO₄, Na-doped SrSO₄, K-doped SrSO₄ and combinations thereof.

An exemplary embodiment of a light emitting apparatus is provided, comprising: a substrate; a plurality of light emitting devices disposed on the substrate arranged in an array, wherein the light emitting device comprises a light emitting chip having a wavelength between 460 nm and 650 nm; an encapsulant material encapsulating the light emitting chip; a phosphor powder dispersed in the encapsulant material, stimulated by light emitted from the light emitting chip to emit light with a wavelength between 700 nm and 1200 nm, wherein the phosphor powder is selected from the group consisting of Cu-doped CdS, Cu-doped SeS, Cu-doped CdTe and combinations thereof.

Another exemplary embodiment of a light emitting apparatus comprises: a substrate; a plurality of light emitting devices disposed on the substrate arranged in an array, wherein the light emitting device comprises a light emitting chip having a wavelength between 460 nm and 650 nm; an encapsulant material encapsulating the light emitting chip; a phosphor powder dispersed in the encapsulant material, stimulated by light emitted from the light emitting chip to emit light with a wavelength between 700 nm and 1200 nm, wherein the phosphor powder is selected from the group consisting of Na-doped BaSO₄, K-doped BaSO₄, Na-doped SrSO₄, K-doped SrSO₄ and combinations thereof.

Yet another exemplary embodiment of a light emitting device comprises: a substrate; a plurality of light emitting chips having a wavelength between 460 nm and 650 nm disposed on the substrate arranged in an array; an encapsulant material formed on the substrate; a phosphor powder dispersed in the encapsulant material, stimulated by light emitted from the light emitting chip to emit light with a wavelength between 700 nm and 1200 nm, wherein the phosphor powder is selected from the group consisting of Cu-doped CdS, Cu-doped SeS, Cu-doped CdTe and combinations thereof.

Yet another exemplary embodiment of a light emitting device comprises: a substrate; a plurality of light emitting chips having a wavelength between 460 nm and 650 nm disposed on the substrate arranged in an array; an encapsulant material formed on the substrate; a phosphor powder dispersed in the encapsulant material, stimulated by light emitted from the light emitting chip to emit light with a wavelength between 700 nm and 1200 nm, wherein the phosphor powder is selected from one of the group consisting of Na-doped BaSO₄, K-doped BaSO₄, Na-doped SrSO₄ and K-doped SrSO₄.

Exemplary embodiments of a light emitting device can effectively emit infrared light with high intensity by utilizing a light emitting chip and phosphor powder.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows one exemplary embodiment of a light emitting device of the invention.

FIG. 2 shows an intensity simulation diagram of one exemplary embodiment of a light emitting device of the invention.

FIG. 3 shows another exemplary embodiment of a light emitting device of the invention.

FIGS. 4A to 4B shows yet another exemplary embodiment of a light emitting device of the invention.

FIG. 5 shows an electronic device using one exemplary embodiment of a light emitting device of the invention.

### DETAILED DESCRIPTION OF INVENTION

The following description is of a mode for carrying out the invention. This description is made for the purpose of illustrating the general principles of the invention and should not be taken in a limiting sense. The scope of the invention is best determined by reference to the appended claims. Wherever possible, the same reference numbers are used in the drawings and the descriptions to refer the same or like parts.

The present invention will be described with respect to embodiments and with reference to certain drawings, but the invention is not limited thereto and is only limited by the claims herein. The drawings described are only schematic and are non-limiting. In the drawings, the size of some of the elements may be exaggerated and not drawn to scale for illustrative purposes. The dimensions and the relative dimensions do not correspond to actual dimensions to practice the invention.

The present invention will be described with respect to embodiments of a method for fabricating a light emitting device package, for example, a light emitting diode package. Note that the light emitting device of embodiments of the invention can be applied in various electronic devices, for example, remote controllers such as image remote controllers or door entry controllers, optical sensors such as smoke sensors or local network signal transceivers, or optical sensing input devices such as optical mice.

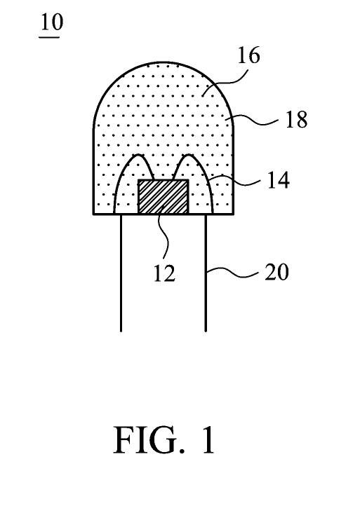

FIG. 1 shows one exemplary embodiment of a light emitting device 10 of the invention. As shown in FIG. 1, a light emitting chip 12, for example, a light emitting diode, is provided. The light emitting chip 12 may emit light in the short wavelength region of 460 to 650 nm. Preferably, the light emitting chip 12 may be a laminated structure comprising GaN or InGaN. For example, the laminated structure may be an Mg-doped GaN (p-GaN) layer, a GaN layer and a Si-doped GaN (n-GaN) layer sequentially laminated on a sapphire substrate. The laminated structure may emit blue light.

In FIG. 1, a conductive wire 14 is electrically connected to the light emitting chip 12. The light emitting chip 12 and the conductive wire 14 are encapsulated using an encapsulant material 18 with a phosphor powder 16 dispersed therein. As shown in FIG. 1, a lead 20 is electrically connected to the conductive wire 14. The lead 20 may provide an external current to drive the light emitting chip 12 emitting light via the conductive wire 14.

The phosphor powder 16 may be stimulated by light to emit infrared light with a wavelength between 700 nm and 1200 nm. The phosphor powder 16 may be selected from the group consisting of Cu-doped CdS (called CdS:Cu), Cu-doped SeS (called SeS:Cu), Cu-doped CdTe (called CdTe:Cu) and combinations thereof. For example, the phosphor powder 16 may comprise Cd₁₋ₓS:Cuₓ, Cd₁₋ₓSe:Cuₓ or Cd₁₋ₓTe:Cuₓ, wherein 0.01<x<0.1. Alternatively, the phosphor powder 16 may also comprise Na-doped BaSO₄ (called BaSO₄: Na), K-doped BaSO₄ (called BaSO₄: K), Na-doped SrSO₄ (called SrSO₄: Na), K-doped SrSO₄ (called SrSO₄: K) and combinations thereof. It is noted that the phosphor powder 16 of Na-doped SrSO₄ or K-doped SrSO₄, wherein alkaline metal may be added to the Na-doped SrSO₄ or K-doped SrSO₄, for example, Sn, Fe or Ni. For example, the phosphor powder 16 may comprise (Ba₁₋ₓSrₓ)SO₄ (Na,K)_{y},(Sn,Fe, Ni)_{z}, wherein 0≦x≦0.0001≦y≦0.1, and 0≦z≦0.01.

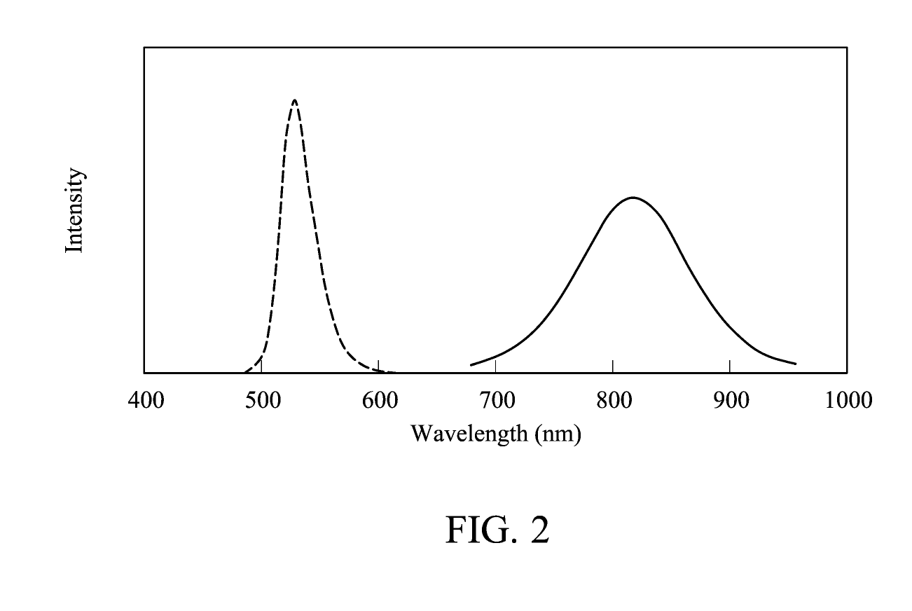

Referring to FIG. 2, FIG. 2 shows an intensity simulation diagram of a photoluminescence spectrum of one exemplary embodiment of a light emitting device of the invention. As shown in FIG. 2, the dot line illustrates the emission wavelength range of the light emitting chip 12. The emission wavelength range of the light emitting chip 12 is between 500 nm and 600 nm, which is in the blue light range. The solid line illustrates the emission wavelength range of the phosphor powder 16. The emission wavelength range of the phosphor powder 16 is between 700 nm and 950 nm, which is in the infrared light range. Because the light emitting chip has higher intensity, the phosphor powder stimulated by the light emitting chip also has higher intensity. Accordingly, a light emitting device emitting infrared light with high intensity is obtained.

Note that the emission wavelength range of the phosphor powder may also be modulated by adjusting the ratio among the elements contained in the phosphor powder, for example, the ratio among CdTe and Cu-doped metals. Additionally, a light filter used to screen out stray light, such as in the blue light range, emitted from the light emitting device, may be optionally disposed on a light emitting surface of the light emitting device to improve light purity of the light emitting device.

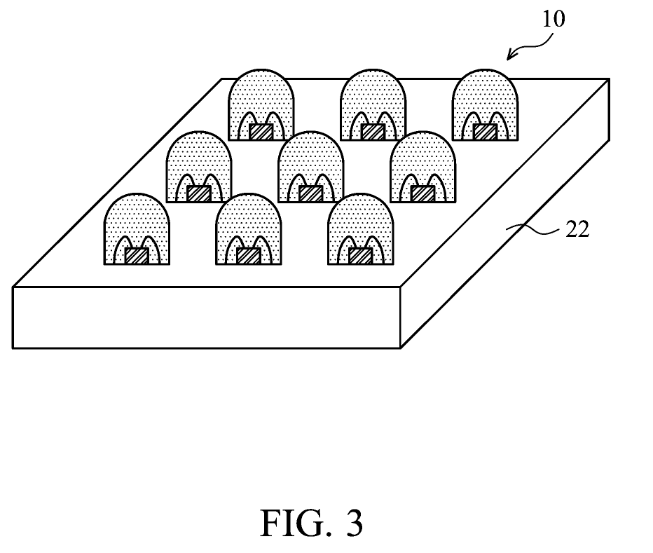

FIG. 3 shows an exemplary embodiment of a light emitting apparatus of the invention. As shown in FIG. 3, a plurality of light emitting devices 10 as described in FIG. 1 is provided. The light emitting devices 10 are disposed on the substrate 22, arranged in an array. In one embodiment, a substrate 22 with sockets and driving circuits formed thereon is provided. Next, the light emitting devices 10 are plugged into the sockets of the substrate 22 to form the light emitting apparatus as shown in FIG. 3.

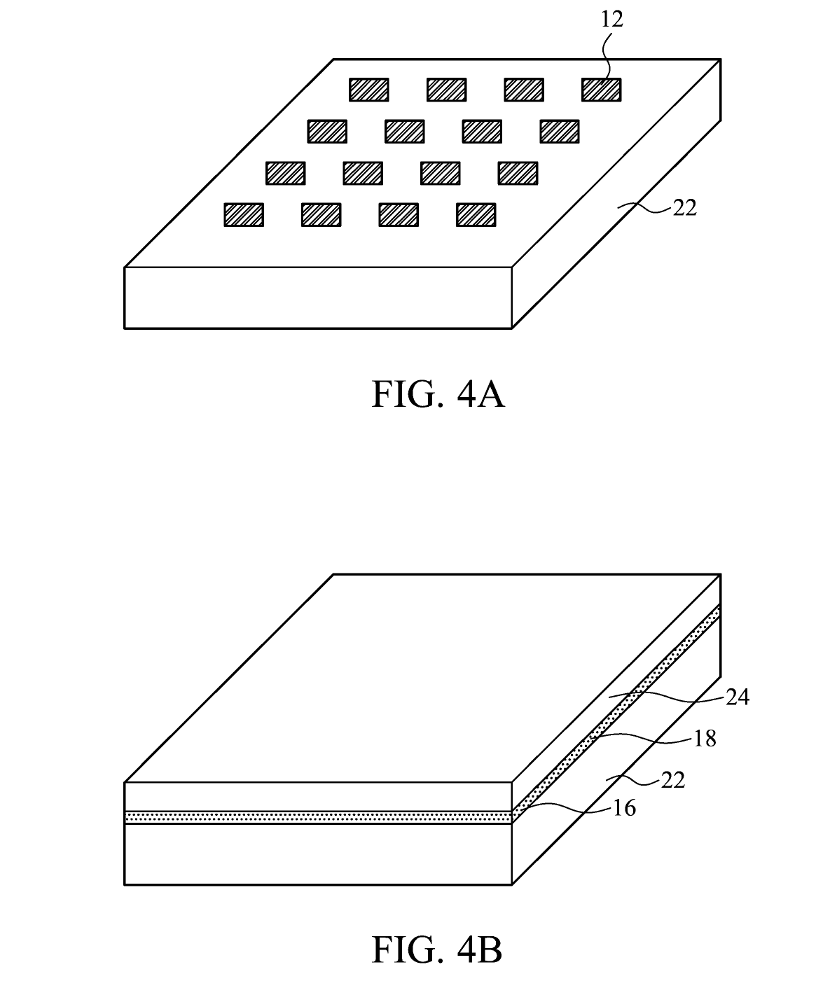

FIGS. 4A to 4B show another exemplary embodiment of a light emitting device of the invention. As shown in FIG. 4A, a substrate 22 is provided, and a plurality of light emitting chips 12 is disposed on the substrate 22, arranged in an array. In one embodiment, first, an adhesive layer (not shown) is formed on the substrate 22 by a method, such as a dispensing method. Next, the light emitting chips 12 are provided, mounted on the substrate 22. It is noted that the adhesive layer may also be entirely formed on the substrate 22 by spin coating.

As shown in FIG. 4B, next, a packaging plate 24 with an encapsulant material 18 coated on a surface thereof is provided, wherein the encapsulant material 18 has a phosphor powder 16 dispersed therein. The packaging plate 24 is disposed over the substrate 22 to cover the light emitting chips 12 and the substrate 22. In this embodiment, the encapsulant material 18 may comprise epoxy. The packaging plate 24 may comprise a transparent substrate allowing light to pass therethrough. Additionally, the substrate 22 may comprise a ceramic plate with gold film, a stainless steel circuit board, a silicon steel piece circuit board, a double-sided aluminum circuit board and so on. The substrate 22 is used as a base to carry the light emitting chips 12.

The materials of the phosphor powder 16 may be the same as the aforementioned embodiments. The phosphor powder 16 may be stimulated by light having a wavelength between 460 nm and 650 nm emitted from the light emitting chips 12 to emit light with a wavelength between 700 nm and 1200 nm.

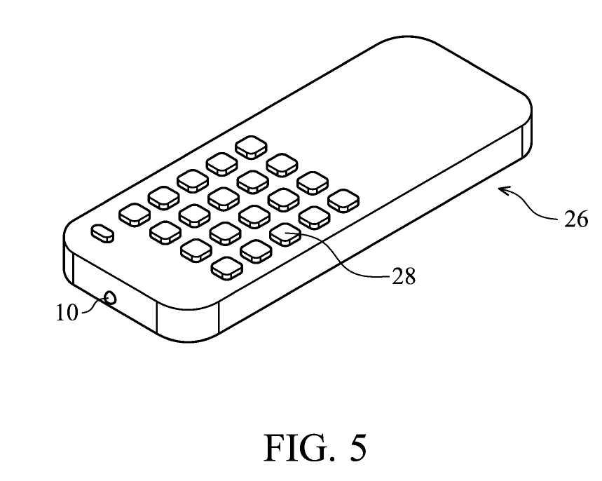

FIG. 5 shows an electronic device using one exemplary embodiment of a light emitting device of the invention. As shown in FIG. 5, a remote controller 26 such as an image controller is provided. The remote controller 26 has a light emitting device 10 and keys 28. The user may input signals via the keys 28. The signals may be transmitted to a signal receiver of an image display device, for example, a television, via the light emitting device 10, thereby controlling operations, for example, such as turning on, turning off or switching the channel of, the image display device. Note that embodiments of the light emitting devices of the invention are not limited to the disclosed embodiments herein. For example, the light emitting device may also comprise door entry controllers, portable instruments, infrared optical mice, smoke sensors or infrared local network signal transceivers, which would be controlled or operated by sensing infrared light.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light emitting device, comprising:
a light emitting chip having a wavelength between 460 nm and 650 nm;
an encapsulant material encapsulating the light emitting chip; and
a phosphor powder dispersed in the encapsulant material, stimulated by light emitted from the light emitting chip to emit light with a wavelength between 700 nm and 1200 nm, wherein the phosphor powder is selected from the group consisting of Cu-doped CdS, Cu-doped SeS, Cu-doped CdTe and combinations thereof.

2. The light emitting device as claimed in claim 1, wherein the phosphor powder comprises Cd₁₋ₓS:Cuₓ, Cd₁₋ₓSe:Cuₓ or Cd₁₋ₓTe:Cuₓ, wherein 0.01<x<0.1.

3. The light emitting device as claimed in claim 1, wherein the phosphor powder is a laminated structure comprising GaN or InGaN.

4. The light emitting device as claimed in claim 3, wherein the laminated structure comprises a sapphire substrate, an Mg-doped GaN layer, a GaN layer and a Si-doped GaN layer, which are sequentially laminated on the sapphire substrate.

5. The light emitting device as claimed in claim 4, wherein the light emitting chip emits light in a blue waveband.

6. The light emitting device as claimed in claim 1, further comprising a conductive wire and a lead, wherein the conductive wire is electrically connected to the lead.

7. The light emitting device as claimed in claim 6, wherein the lead provides an external current to drive the light emitting chip to emit light via the conductive wire.

8. An electronic device having the light emitting device as claimed in claim 1, wherein the electronic device comprises an optical sensing input device, a remote controller or a local network signal transceiver.

9. A light emitting device, comprising:
a light emitting chip having a wavelength between 460 nm and 650 nm;
an encapsulant material encapsulating the light emitting chip; and
a phosphor powder dispersed in the encapsulant material, stimulated by light emitted from the light emitting chip to emit light with a wavelength between 700 nm and 1200 nm, wherein the phosphor powder is selected from the group consisting of Na-doped BaSO₄, K-doped BaSO₄, Na-doped SrSO₄, K-doped SrSO₄ and combinations thereof.

10. The light emitting device as claimed in claim 9, wherein the phosphor powder comprises Na-doped SrSO₄ or K-doped SrSO₄, wherein alkaline metal is added to the Na-doped SrSO₄ or K-doped SrSO₄.

11. The light emitting device as claimed in claim 10, wherein the phosphor powder further comprises Sn-doped, Fe-doped or Ni-doped phosphor powder.

12. The light emitting device as claimed in claim 11, wherein the phosphor powder is (Ba₁₋ₓSrₓ)SO₄ (Na,K)_{y},(Sn,Fe, Ni)_{z}, wherein 0≦x≦1, 0.0001≦y≦0.1, and 0≦z≦0.01.

13. The light emitting device as claimed in claim 9, wherein the phosphor powder is a laminated structure comprising GaN or InGaN.

14. The light emitting device as claimed in claim 13, wherein the laminated structure comprises a sapphire substrate, an Mg-doped GaN layer, a GaN layer and a Si-doped GaN layer, which are sequentially laminated on the sapphire substrate.

15. The light emitting device as claimed in claim 14, wherein the light emitting chip emits light in a blue waveband.

16. The light emitting device as claimed in claim 9, further comprising a conductive wire and a lead, wherein the conductive wire is electrically connected to the lead.

17. The light emitting device as claimed in claim 16, wherein the lead provides an external current to drive the light emitting chip to emit light via the conductive wire.

18. An electronic device having the light emitting device as claimed in claim 9, wherein the electronic device comprises an optical sensing input device, a remote controller or a local network signal transceiver.

19. A light emitting apparatus, comprising:
a substrate; and
a plurality of light emitting devices as claimed in claim 1 disposed on the substrate, arranged in an array.

20. A light emitting apparatus, comprising:
a substrate; and
a plurality of light emitting devices as claimed in claim 9 disposed on the substrate arranged in an array.

21. A light emitting device, comprising:
a substrate;
a plurality of light emitting chips having a wavelength between 460 nm and 650 nm disposed on the substrate, arranged in an array;
an encapsulant material formed on the substrate; and
a phosphor powder dispersed in the encapsulant material, stimulated by light emitted from the light emitting chip to emit light with a wavelength between 700 nm and 1200 nm, wherein the phosphor powder is selected from the group consisting of Cu-doped CdS, Cu-doped SeS, Cu-doped CdTe and combinations thereof.

22. The light emitting device as claimed in claim 21, wherein the phosphor powder comprises Cd₁₋ₓS:Cuₓ, Cd₁₋ₓSe:Cuₓ or Cd₁₋ₓTe:Cuₓ, wherein 0.01<x<0.1.

23. The light emitting device as claimed in claim 21, further comprising a packaging plate covering the light emitting chips.

24. The light emitting device as claimed in claim 21, wherein the light emitting chips are laminated structures comprising GaN or InGaN.

25. The light emitting device as claimed in claim 24, wherein the laminated structure comprises a sapphire substrate, an Mg-doped GaN layer, a GaN layer and a Si-doped GaN layer, which are sequentially laminated on the sapphire substrate.

26. A light emitting device, comprising:
a substrate;
a plurality of light emitting chips having a wavelength between 460 nm and 650 nm disposed on the substrate, arranged in an array;
an encapsulant material formed on the substrate; and
a phosphor powder dispersed in the encapsulant material, stimulated by light emitted from the light emitting chip to emit light with a wavelength between 700 nm and 1200 nm, wherein the phosphor powder is selected from one of the group consisting of Na-doped BaSO₄, K-doped BaSO₄, Na-doped SrSO₄ and K-doped SrSO₄.

27. The light emitting device as claimed in claim 26, further comprising a packaging plate covering the light emitting chips.

28. The light emitting device as claimed in claim 26, wherein the laminated structure comprises GaN or InGaN, and is comprised of the light emitting chips.

29. The light emitting device as claimed in claim 28, wherein the laminated structure comprises a sapphire substrate, an Mg-doped GaN layer, a GaN layer and a Si-doped GaN layer, which are sequentially laminated on the sapphire substrate.

30. The light emitting device as claimed in claim 26, wherein the phosphor powder comprises Na-doped SrSO₄ or K-doped SrSO₄, wherein alkaline metal is added to the Na-doped SrSO₄ or K-doped SrSO₄.

31. The light emitting device as claimed in claim 30, wherein the phosphor powder further comprises Sn-doped, Fe-doped or Ni-doped phosphor powder.

32. The light emitting device as claimed in claim 31, wherein the phosphor powder is (Ba₁₋ₓSrₓ)SO₄ (Na,K)_{y},(Sn,Fe, Ni)_{z}, wherein 0≦x≦1, 0.0001≦y≦0.1, and 0≦z≦0.01.
